(19) United States
(12) Patent Application Publication
(10) Pub. No.: US 2016/0311721 A1
(43) Pub. Date: Oct. 27, 2016

(54) GLASS COMPOSITION AND ELECTRODE COMPOSITION

(71) Applicant: DONGJIN SEMI CHEM CO., LTD., lncheon (KR)

(72) Inventors: Kun-Ho HWANG, Hwaseong (KR); Hwa-Young NOH, Hwaseong (KR); Yoo-Seong KIM, Hwaseong (KR); Eun-Soo JANG, Hwaseong (KR); Sang-Duck LEE, Hwaseong (KR)

(21) Appl. No.: 15/203,949

(22) Filed: Jul. 7, 2016

Related U.S. Application Data
(63) Continuation of application No. PCT/KR2015/000523, filed on Jan. 19, 2015.

(30) Foreign Application Priority Data
Jan. 28, 2014 (KR) 10-2014-0010312

(51) Int. Cl. C03C 8/18; H01L 31/0224; C03C 4/14; C03C 8/10; C03C 3/12; C03C 3/07

(52) U.S. Cl. CPC C03C 8/18; C03C 3/122; C03C 3/07; C03C 4/14; C03C 8/10; H01L 31/022433; C03C 2204/00; C03C 2205/00

(57) ABSTRACT

Provided are a glass composition and an electrode composition including the same. More particularly, provided are a glass composition having a low glass transition temperature and showing three or more exothermic peaks, and an electrode composition using the same, which realizes low series resistance and a high fill factor to improve energy conversion efficiency

### CROSS-REFERENCES TO RELATED APPLICATION

This application is a Continuation application of a National Stage application of PCT/KR2015/000523 filed on Jan. 19, 2015, which claims priority to Korean Patent Application No. 10-2014-0010312 filed on Jan. 28, 2014, the contents of which are incorporated herein by reference.

### TECHNICAL FIELD

The present disclosure relates to a glass composition for improving contact resistance between an electrode and a substrate and inhibiting shunting of a pn junction, and an electrode composition for a solar cell using the same.

### BACKGROUND ART

A solar cell electrode consists of a conductive metal powder, a glass powder, an organic binder, a solvent, etc. as main components. Of them, the glass powder plays a very important function in inducing contact resistance between an electrode material and a cell of the pn junction structure.

To obtain excellent conversion efficiency of a crystalline solar cell, reactivity of the glass powder at a high sintering temperature (700° C. to 900° C.) must be improved. Glass powder having excellent reactivity increases Ag precipitates on the surface of an n layer to improve contact resistance, leading to improvement of series resistance and fill factor. Thus, it is possible to manufacture a high-efficiency solar cell. By improvement of contact resistance, stable series resistance may also be obtained in a high-resistance substrate such as a high sheet resistance (80Ω/□ or more) structure.

However, general glass powder continuously induces a diffusion reaction at a high temperature of 700° C. to 900° C. to cause a shunting phenomenon, and therefore, the conductive component (Ag) on the surface of the n layer reaches the p layer.

To prevent this problem, Korean Patent Publication No. 10-2011-0105682 discloses a composition using a crystallized glass powder. According to this method, the crystallized glass prevents the continuous diffusion reaction to reduce the shunting phenomenon, but it is not easy to control a crystallization reaction at different sintering temperatures, thereby causing a problem of a low margin for the sintering temperature.

Further, Korean Patent Publication No. 10-2010-0125273 discloses a Bi-based glass composition including no PbO. According to this method, the PbO component that rapidly reacts is not included to reduce Ag precipitates, and therefore, it is difficult to obtain excellent contact resistance. In addition, upon application of a high sheet resistance cell (80Ω/□ or more), series resistance may be increased.

US Patent Publication No. 2011-0232746 discloses a thin film paste composition including Pb—Te—B oxide as an essential component. However, this method may cause a reduction in flowability of a glass melt and a reduction in wettability of a substrate by a glass former B₂O₃.

### DISCLOSURE

### Technical Problem

An object of the present invention is to provide a glass composition which has low contact resistance with a cell, prevents shunting of a pn junction structure, has a low glass temperature, and in particular, shows three or more exothermic peaks.

Another object of the present invention is to provide an electrode composition for a solar cell, which shows low series resistance and a high fill factor by using the glass composition, thereby improving energy conversion efficiency.

### Technical Solution

The present invention provides a glass composition which shows three or more exothermic peaks in a range of 200° C. to 600° C., as measured by differential scanning calorimetry.

The glass composition may include PbO, TeO₂, and Li₂O. The glass composition may further include one or more metal oxides selected from the group consisting of Na₂O, K₂O, Bi₂O₃, and SiO₂. In this case, the glass composition may have a metal oxide composition of PbO, TeO₂, Li₂O, and Bi₂O₃; PbO, TeO₂, Li₂O, Na₂O, and K₂O; PbO, TeO₂, Li₂O, Na₂O, K₂O, and SiO₂; PbO, TeO₂, Li₂O, Na₂O, K₂O, and Bi₂O₃; or PbO, TeO₂, Li₂O, Na₂O, K₂O, Bi₂O₃, and SiO₂.

Further, the glass composition may not include a metal component or a metal oxide other than the above-described metal oxides, except impurities.

In the glass composition, 20% by weight to 70% by weight of PbO, 20% by weight to 70% by weight of TeO₂, and 0.1% by weight to 20% by weight of Li₂O may be included, based on the total weight of the glass composition.

In addition, an amount of the metal oxide further included may be 0.1 to 30 parts by weight, based on the total 100 parts by weight of PbO, TeO₂, and Li₂O.

The glass composition preferably has a glass transition temperature (Tg) of 200° C. to 400° C.

The present invention also provides an electrode composition for a solar cell, which is a paste composition including a conductive particle, a glass powder, a binder, and a solvent, in which the glass powder may include the above-described glass composition.

The glass powder may be included in an amount of 0.1% by weight to 20% by weight, based on the total paste composition.

The conductive particle may include Ag, Cu, or Ni particles having an average diameter of 10 nm to 10 um.

The binder may be one or more selected from the group consisting of cellulose derivatives such as methyl cellulose, ethyl cellulose, nitrocellulose, hydroxy cellulose, or cellulose acetate; an acrylic resin; an alkyd resin; a polypropylene-based resin; a polyvinyl chloride-based resin; a polyurethane-based resin; an epoxy-based resin; a silicon-based resin; a rosin-based resin; a terpene-based resin; a phenolic resin; an aliphatic petroleum resin; an acrylic ester-based resin; a xylene-based resin; a cumaronindene-based resin; a styrene-based resin; a dicyclopentadiene-based resin; a polybutene-based resin; a polyether-based resin; a urea-based resin; a melamine-based resin; a vinyl acetate-based resin; and a polyisobutyl-based resin.

The solvent may be one or more selected from the group consisting of butyl carbitol acetate, butyl carbitol, propylene glycol monomethyl ether, dipropylene glycol monomethyl ether, propylene glycol monomethyl ether propionate, ethyl ether propionate, propylene glycol monomethyl ether acetate, terpineol, texanol, (dimethylamino)formaldehyde, methyl ethyl ketone, gamma-butyrolactone, and ethyl lactate.

The electrode composition for a solar cell may be used to form a front electrode on a substrate having sheet resistance of 80Ω/□ or more.

### Effect of the Invention

A glass composition according to the present invention is a crystallized glass powder having a low glass transition temperature (200° C.˜400° C.). When an electrode composition for a solar cell including this glass composition is used to form an electrode, low series resistance and a high fill factor may be obtained to improve energy conversion efficiency. Further, the glass composition of the present invention exhibits three or more exothermic peaks in a predetermined temperature region, thereby showing low contact resistance with a cell. In addition, in the present invention, the glass composition showing three or more exothermic peaks is used to manufacture a front electrode of a solar cell, thereby inhibiting shunting of the pn junction, that is, penetration of a conductive component formed on the n layer into the p layer. Moreover, the present invention has an effect of improving the margin for sintering temperature and time.

### BRIEF DESCRIPTION OF DRAWINGS

FIG. 1 shows the result of thermal analysis of a glass composition of Example 1, which was measured by differential scanning calorimetry (DSC);

FIG. 2 shows the result of thermal analysis of a glass composition of Example 2, which was measured by differential scanning calorimetry (DSC);

FIG. 3 shows the result of thermal analysis of a glass composition of Example 3, which was measured by differential scanning calorimetry (DSC);

FIG. 4 shows the result of thermal analysis of a glass composition of Comparative Example 1, which was measured by differential scanning calorimetry (DSC);

FIG. 5 shows the result of measuring contact resistance of Example 9 and Comparative Example 6, which was measured by TLM patterns;

FIG. 6 shows the result of measuring contact resistance of Example 9 and Comparative Example 6, which was measured by a CoreScan tester; and

FIG. 7 shows the result of measuring the surface of electrodes of Example 9 and Comparative Example 6, which was measured by scanning electron microscopy (SEM).

### DETAILED DESCRIPTION OF THE EMBODIMENTS

Hereinafter, the present invention will be described in more detail.

According to an embodiment of the present invention, provided is a glass composition which shows three or more exothermic peaks in a range of 200° C. to 600° C., as measured by differential scanning calorimetry.

The glass composition of the present invention includes PbO, TeO₂, and Li₂O. Further, the glass composition of the present invention may further include one or more metal oxides selected from the group consisting of Na₂O, K₂O, Bi₂O₃, and SiO₂.

In this regard, the glass composition mentioned in the present invention means a glass powder or a glass frit, and is a component used in an electrode composition for a solar cell. Due to the above-described particular composition, the glass composition of the present invention is characterized in that it shows three or more exothermic peaks in a range of 200° C. or higher, as measured by differential scanning calorimetry (DSC).

In particular, the glass composition according to the present invention is characterized in that it shows one or more exothermic peaks in a range of 200° C. to 400° C., as measured by differential scanning calorimetry. Further, the glass composition of the present invention may show two or more, preferably three or more, exothermic peaks in a range of 400° C. to 600° C., as measured by differential scanning calorimetry. Most preferably, the glass composition of the present invention may show four to five exothermic peaks in a range of 200° C. to 600° C. or in a range of 400° C. to 600° C., as measured by differential scanning calorimetry (DSC).

Therefore, the glass composition of the present invention may prevent shunting of the pn junction structure, compared to the previous composition. Further, the glass composition according to the present invention is a low temperature glass powder having a glass transition temperature (Tg) of 200° C.˜400° C., its reactivity and flowability are excellent, and it is easy to control a crystallization reaction. Therefore, when the glass composition is used in an electrode composition, Ag precipitates on the surface of the n layer are increased to improve contact resistance, thereby realizing high efficiency of a solar cell.

Further, the glass composition of the present invention may exhibit a low glass transition temperature as in the above described temperature range, compared to the previous composition. More preferably, the glass composition of the present invention may exhibit a glass transition temperature (Tg) of 200° C. to 300° C., which is lower than that of the previous composition.

In this regard, if the glass transition temperature of the glass composition is higher than 400° C., there is a problem that it is difficult to obtain a uniform contact property due to high viscosity of the glass during the sintering process of the Ag electrode. If the glass transition temperature of the glass composition is lower than 200° C., there is a problem that excessive sintering flow behavior may cause pattern spreading around electrode patterns. Although the previous glass composition shows a low glass transition temperature, its composition does not satisfy the particular essential components and the content range suggested in the present invention, and therefore, it may not exhibit multi-exothermic peaks.

Specifically, the glass composition of the present invention is a glass powder showing a characteristic that a multistep reaction is induced by the above-described particular components to show three or more exothermic peaks in thermal analysis. Therefore, when the glass composition of the present invention having the multi-exothermic characteristic during the sintering process is used, low contact resistance may be obtained.

In the diffusion reaction of the sintering process upon manufacturing an electrode of a solar cell, multistep control is possible, thereby inhibiting a shunting phenomenon, that is, penetration of the conductive component (Ag) on the surface of the n layer into the p layer. In other words, it is important to control a high-temperature diffusion property in the solar cell structure having a low n layer thickness with high sheet resistance. In the present invention, shunting of the pn junction structure may be prevented by controlling an excess flow behavior of the glass powder. Accordingly, it is possible to realize high efficiency of a crystalline solar cell by increasing a sintering margin and stability in a high sheet resistance cell (80Ω/□ or more) structure, and improving contact resistance.

This glass composition of the present invention may not include a metal component or a metal oxide other than the above described particular metal oxides.

Therefore, the glass composition of the preset invention includes PbO, TeO₂, and Li₂O-based compounds as essential components, and in particular, it does not include B₂O₃ and P₂O₅ components which are generally used in the previous glass composition. Further, the glass composition of the present invention contributes to multiple exothermic peaks as described above, even though it includes only TeO₂, together with Pb and Li oxides.

In this regard, when B₂O₃ is included in the glass composition, flowability of a melt and wettability of a substrate may be reduced, as described above. In addition, when P₂O₅ is included in the glass composition, Tg is increased to cause reduction in flowability of the melt and wettability of the substrate, and P₂O₅ functions as an impurity to greatly increase contact resistance (Rc). Moreover, if any one of Pb, Te, and Li components is not used, the conductive component (Ag) reaches the p layer due to continuous etching of the surface of the n layer by the glass melt during the sintering process, resulting in a shunting phenomenon.

In the present invention, the contents of the three essential components may preferably be 20% by weight to 70% by weight of PbO, 20% by weight to 70% by weight of TeO₂, and 0.1% by weight to 20% by weight of Li₂O, based on the total weight of the glass composition.

Further, the glass composition includes a metal oxide such as Na₂O as an optional additive component, thereby expecting a synergistic effect of forming a low glass transition temperature and improving reactivity between a Ag electrode and an anti-reflection layer to form uniform contact resistance. For example, as described above, the glass composition of the present invention may further include one or more metal oxides selected from the group consisting of Na₂O, K₂O, Bi₂O₃, and SiO₂, together with the above-described three essential components. In addition, when the metal oxide is further used in the glass composition, an amount of the metal oxide may be properly controlled within the range of 0.1 parts by weight to 30 parts by weight, based on the total 100 parts by weight of the three essential components, PbO, TeO₂, and Li₂O.

Preferably, the glass composition of the present invention includes a composition of PbO, TeO₂, Li₂O, and Bi₂O₃; PbO, TeO₂, Li₂O, Na₂O, and K₂O; PbO, TeO₂, Li₂O, Na₂O, K₂O, and SiO₂; PbO, TeO₂, Li₂O, Na₂O, K₂O, and Bi₂O₃; or PbO, TeO₂, Li₂O, Na₂O, K₂O, Bi₂O₃, and SiO₂. As mentioned above, the glass composition may not include a metal component or a metal oxide other than the above-described metal oxides, except impurities. That is, the glass composition of the present invention includes only the above components.

On the other hand, if the content of the PbO component is less than 20% by weight, there are problems that wettability of the substrate is reduced, and the anti-reflection layer is not penetrated. If the content of the PbO component is more than 70% by weight, there is a problem that vitrification is difficult. Further, if the content of the TeO₂ component is less than 20% by weight, there are problems that a multi-step reaction control is impossible, shunting occurs, and thus the conductive component (Ag) on the surface of the n layer reaches the p layer. If the content of the TeO₂ component is more than 70% by weight, there is a problem that vitrification is difficult. Furthermore, if the content of the Li₂O component is less than 0.1% by weight, there is a problem that adhesion is reduced. If the content of the Li₂O component is more than 20% by weight, there is a problem that a thermal expansion coefficient is increased to generate microcracks on the surface.

If the content of the metal compound is more than 30 parts by weight, Na₂O or K₂O increases the alkali content and thus vitrification is difficult, and Bi₂O₃ or SiO₂ increases the glass transition temperature, and therefore it is difficult to reduce high-temperature viscosity of the glass during the sintering process, thereby reducing wettability of the substrate.

According to another aspect of the present invention, provided is an electrode composition for a solar cell, which is a paste composition including a conductive particle, a glass powder, a binder, and a solvent, in which the glass powder may include the above-described glass composition.

According to the present invention, the glass composition having the above-described characteristics of low contact resistance, having three or more exothermic peaks in a predetermined temperature range, and preventing shunting of the pn junction structure is included in an electrode composition for a solar cell to obtain low series resistance and a high fill factor of the solar cell, thereby improving energy conversion efficiency.

In this regard, the electrode composition according to the present invention is preferably used in manufacturing a front electrode of the solar cell. Further, the electrode composition of the present invention may be used to manufacture a general substrate having low sheet resistance, and it may also be used to manufacture a solar cell of a high sheet resistance structure, including a substrate having sheet resistance of 80Ω/□ or more. Therefore, the electrode composition for the solar cell of the present invention may be most preferably used in forming the front electrode on the substrate having sheet resistance of 80Ω/□ or more.

Meanwhile, in the electrode composition for the solar cell of the present invention, the content of the glass powder may be preferably 0.1% by weight to 20% by weight, and more preferably 0.5% by weight to 5% by weight, based on the total paste composition.

The conductive particle may include Ag, Cu, or Ni particles having an average particle size of 10 nm to 10 um, and preferably, Ag particles. In this regard, Ag particles may be any one of spherical, non-spherical, and flake-shaped particles, but there is no particular limitation in the shape, and these Ag particles may be used in a mixture thereof, if necessary. The content of the conductive particle may be 45% by weight to 95% by weight, based on the total paste composition.

The binder may be any of hydrophobic and hydrophilic binders, and the binder may be one or more selected from the group consisting of cellulose derivatives such as methyl cellulose, ethyl cellulose, nitrocellulose, hydroxy cellulose, or cellulose acetate; an acrylic resin; an alkyd resin; a polypropylene-based resin; a polyvinyl chloride-based resin; a polyurethane-based resin; an epoxy-based resin; a silicon-based resin; a rosin-based resin; a terpene-based resin; a phenolic resin; an aliphatic petroleum resin; an acrylic ester-based resin; a xylene-based resin; a cumaronindene-based resin; a styrene-based resin; a dicyclopentadiene-based resin; a polybutene-based resin; a polyether-based resin; a urea-based resin; a melamine-based resin; a vinyl acetate-based resin; and a polyisobutyl-based resin. The content of the binder may be 0.1% by weight to 10% by weight, based on the total paste composition.

The solvent may be any of hydrophobic and hydrophilic solvents, and the solvent may be one or more selected from the group consisting of butyl carbitol acetate, butyl carbitol, propylene glycol monomethyl ether, dipropylene glycol monomethyl ether, propylene glycol monomethyl ether propionate, ethyl ether propionate, propylene glycol monomethyl ether acetate, terpineol, texanol, (dimethylamino)formaldehyde, methylethylketone, gamma-butyrolactone and ethyl lactate. The solvent may be used in an amount sufficient to dissolve the binder, and the range is not particularly limited. For example, the content of the solvent may be 1% by weight to 40% by weight, based on the total paste composition.

The electrode composition for the solar cell of the present invention may further include an additive, if necessary, and for example, an antifoaming agent, a dispersing agent, a plasticizer, etc. may be used. The content of the additive may be 0.01 parts by weight to 10 parts by weight, based on 100 parts by weight of the electrode composition for the solar cell.

The electrode composition for the solar cell of the present invention may be used to manufacture a front electrode, and a manufacturing method is not particularly limited, except that the electrode composition of the present invention and a substrate having high sheet resistance are used. In the present invention, therefore, the solar cell may be manufactured according to a method that is well known in the art.

For example, a general Ag paste composition is printed on a silicon substrate, and then dried to form an Ag back electrode. An Al paste composition is printed in an area with an overlap over a part of this Ag back electrode, and then dried to form an Al electrode. Thereafter, the electrode composition for the solar cell of the present invention may be printed on the entire surface of the silicon substrate, and then dried to form the front electrode for the solar cell. In this regard, the front electrode may be formed using finger line and bus bar patterns.

Further, in the present invention, respective paste compositions for forming the front electrode and the back electrode are coated on the substrate by using a general method such as screen printing, a doctor blade, inkjet printing, or gravure printing. After coating the electrode composition, temperature ranges for drying and sintering are not also particularly limited.

The substrate used in the present invention may be a silicon substrate used in the front electrode, which is included in a silicon solar cell, and the substrate may have sheet resistance of 80Ω/□ or more.

Drying of the electrode composition may be performed at a temperature of 150 C to 350° C. for 1 min to 30 min, and sintering may be performed at a maximum temperature of 750° C. to 950° C. for several s to 5 min.

Additionally, the solar cell of the present invention may be provided with an emitter layer, an anti-reflection layer, etc., which are well known in the art.

Hereinafter, the present invention will be described in more detail with reference to the following examples and comparative examples. However, these examples are for illustrative purposes only, and the invention is not intended to be limited by these examples.

### Examples 1 to 6 and Comparative Examples 1 to 5

Glass compositions of Examples and Comparative Examples were prepared according to compositions and contents as in the following Tables 1 and 2.

TABLE 1

| | Exam- | Exam- | Exam- | Exam- | Exam- | Exam- |
|---|---|---|---|---|---|---|
| Component | ple 1 | ple 2 | ple 3 | ple 4 | ple 5 | ple 6 |
| PbO | 46.9 | 37.43 | 44.97 | 59.26 | 47.71 | 65.96 |
| (wt %) | | | | | | |
| TeO₂ | 49.0 | 58.83 | 54.29 | 36.5 | 50.4 | 30.85 |
| (wt %) | | | | | | |
| Li₂O | 4.1 | 3.74 | 0.74 | 4.24 | 1.89 | 3.19 |
| (wt %) | | | | | | |
| Total | 100 | 100 | 100 | 100 | 100 | 100 |
| Na₂O | — | 2.67 | — | 3.7 | 1.78 | 1.59 |
| (parts by | | | | | | |
| weight) | | | | | | |
| K₂O | — | 2.14 | — | 2.11 | 2.11 | 2.66 |
| (parts by | | | | | | |
| weight) | | | | | | |
| Bi₂O₃ | — | — | 5.82 | — | 7.58 | 1.1 |
| (parts by | | | | | | |
| weight) | | | | | | |
| SiO₂ | — | 2.14 | — | — | | 1.1 |
| (parts by | | | | | | |
| weight) | | | | | | |

TABLE 2

| | Compar- | Compar- | Compar- | Compar- | Compar- |
|---|---|---|---|---|---|
| | ative | ative | ative | ative | ative |
| | Example | Example | Example | Example | Example |
| Component | 1 | 2 | 3 | 4 | 5 |
| PbO | 73.18 | 48.01 | 95.54 | — | 75 |
| (wt %) | | | | | |
| TeO₂ | 24.61 | 51.5 | — | 85.71 | 25 |
| (wt %) | | | | | |
| Li₂O | 2.21 | 0.49 | 4.46 | 14.29 | — |
| (wt %) | | | | | |
| Total | 100 | 100 | 100 | 100 | 100 |
| Na₂O | 1.17 | — | 1.79 | — | — |
| (parts by | | | | | |
| weight) | | | | | |
| K₂O | 2.34 | — | — | 4.29 | 1.88 |
| (parts by | | | | | |
| weight) | | | | | |
| Bi₂O₃ | — | 7.6 | 50 | — | — |
| (parts by | | | | | |
| weight) | | | | | |
| B₂O₃ | 0.39 | 0.55 | — | — | — |
| (parts by | | | | | |
| weight) | | | | | |
| TiO₂ | — | 2.6 | — | 6 | 1.88 |
| (parts by | | | | | |
| weight) | | | | | |
| Al₂O₃ | 5.34 | — | — | 3.71 | 6.25 |
| (parts by | | | | | |
| weight) | | | | | |
| CuO | 0.26 | — | — | — | — |
| (parts by | | | | | |
| weight) | | | | | |
| P₂O₅ | 14.44 | — | — | — | — |
| (parts by | | | | | |
| weight) | | | | | |
| SiO₂ | 5.86 | — | 5.86 | 15.14 | 2.3 |
| (parts by | | | | | |
| weight) | | | | | |

### Examples 7 to 9 and Comparative Examples 6 and 7

Conductive pastes including a conductive particle, a glass powder, and a binder-dissolved solvent were prepared according to compositions and contents as in the following Table 3 (unit: wt %).

In detail, each of the glass compositions was mixed with a vehicle (a binder and a solvent dissolving the binder) using a PLM mixer, and then a conductive particle (Ag) was added thereto, followed by secondary PLM mixing. Each paste obtained by mixing was kneaded by using a 3-mill roll, and finally, a paste for a solar cell electrode was prepared.

TABLE 3

| | | | | | Compara- | Compara- |
|---|---|---|---|---|---|---|
| | | Exam- | Exam- | Exam- | tive Ex- | tive Ex- |
| | | ple 7 | ple 8 | ple 9 | ample 6 | ample 7 |
| Conductive particle* | | 88.5 | 88.5 | 88.5 | 88.5 | 88.5 |
| Glass | Example 1 | 2.5 | — | — | — | — |
| compo- | Example 2 | — | 2.5 | — | — | — |
| sition | Example 3 | — | — | 2.5 | — | — |
| | Compara- | — | — | — | 2.5 | — |
| | tive Ex- | | | | | |
| | ample 1 | | | | | |
| | Compara- | — | — | — | — | 2.5 |
| | tive Ex- | | | | | |
| | ample 2 | | | | | |

| | | | | | |
|---|---|---|---|---|---|
| Binder** | 2 | 2 | 2 | 2 | 2 |
| Solvent*** | 7 | 7 | 7 | 7 | 7 |

note)
*Conductive particle: Ag particle having an average particle size of 1.8 um
**Binder: Ethyl cellulose
***Solvent: A mixture of butyl carbitol acetate (BCA) and texanol at a weight ratio of 6:4

### Experimental Example 1

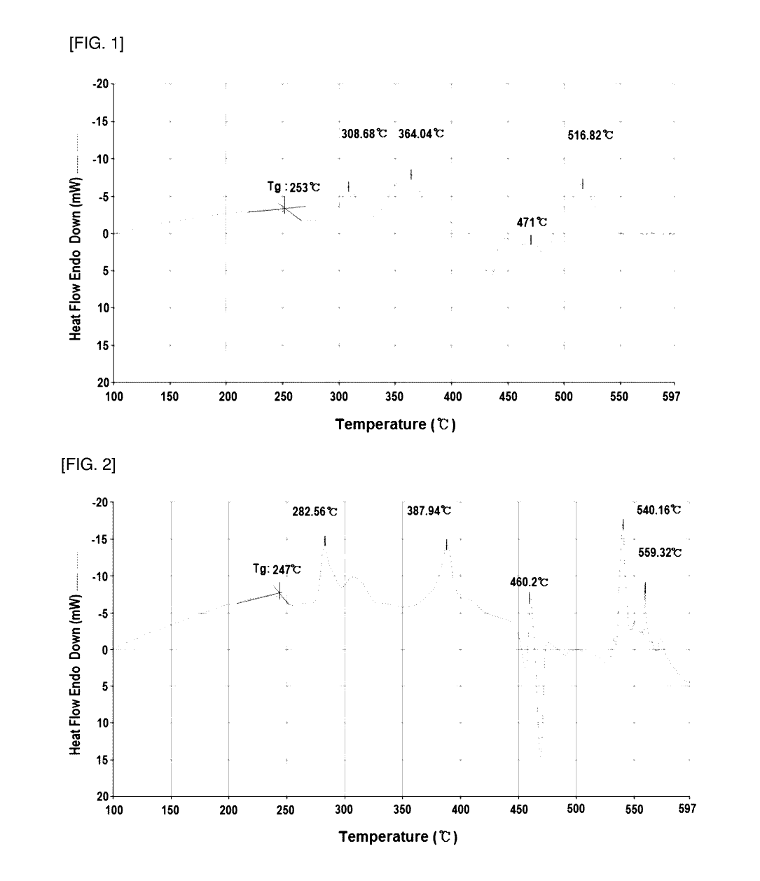

With respect to the glass compositions of Examples 1 to 3 and Comparative Examples 1 and 2, glass transition temperature (Tg) and exothermic peaks were measured with a differential scanning calorimeter (DSC). The results are given in Table 4. Further, the results of differential scanning calorimetry of Examples 1 to 3 and Comparative Example 1 are given in FIGS. 1 to 4.

TABLE 4

| | | | | | Compara- | Compara- |
|---|---|---|---|---|---|---|
| | | Exam- | Exam- | Exam- | tive Ex- | tive Ex- |
| | | ple 1 | ple 2 | ple 3 | ample 1 | ample 2 |
| Glass transition | | 254 | 247 | 245 | 356 | 436 |
| temperature (Tg) | | | | | | |
| Exo- | Peak 1 | 308.6 | 282.5 | 281 | 415 | 530 |
| thermic | Peak 2 | 364 | 387.9 | 302 | 471 | 646 |
| temper- | Peak 3 | 471 | 460.2 | 402 | — | — |
| ature | Peak 4 | 516.8 | 540 | 524 | — | — |
| | Peak 5 | — | 559 | — | — | — |
| | Total | Total of | Total of | Total of | Total of | Total of |
| | number | 4 peaks | 5 peaks | 4 peaks | 2 peaks | 2 peaks |
| | of peaks | | | | | |

### Experimental Example 2

Solar cells were manufactured using conductive pastes of Example 9 and Comparative Example 6 according to a general method.

A silicon wafer for printing the electrode was a high sheet resistance cell having sheet resistance of 90Ω/□, and a paste for a Ag back electrode was printed on the silicon substrate, and then dried to form the Ag back electrode. Next, a paste for an Al back electrode was screen-printed to be overlapped with a part of the Ag back electrode, and then dried. Each paste was dried at a temperature of 170° C.

The pastes of the examples and comparative examples were printed on the entire surface of the silicon wafer by screen printing, followed by a drying process. In this regard, a mask for printing was 360-mesh having the entire thickness of 47 μm, and patterns were formed on the front electrode by using finger lines having a width of 40 μm and bus bar patterns having a width of 1.5 mm. After drying at 170° C., sintering was performed to manufacture solar cells, and performances thereof were evaluated as follows.

(1) Contact Resistance

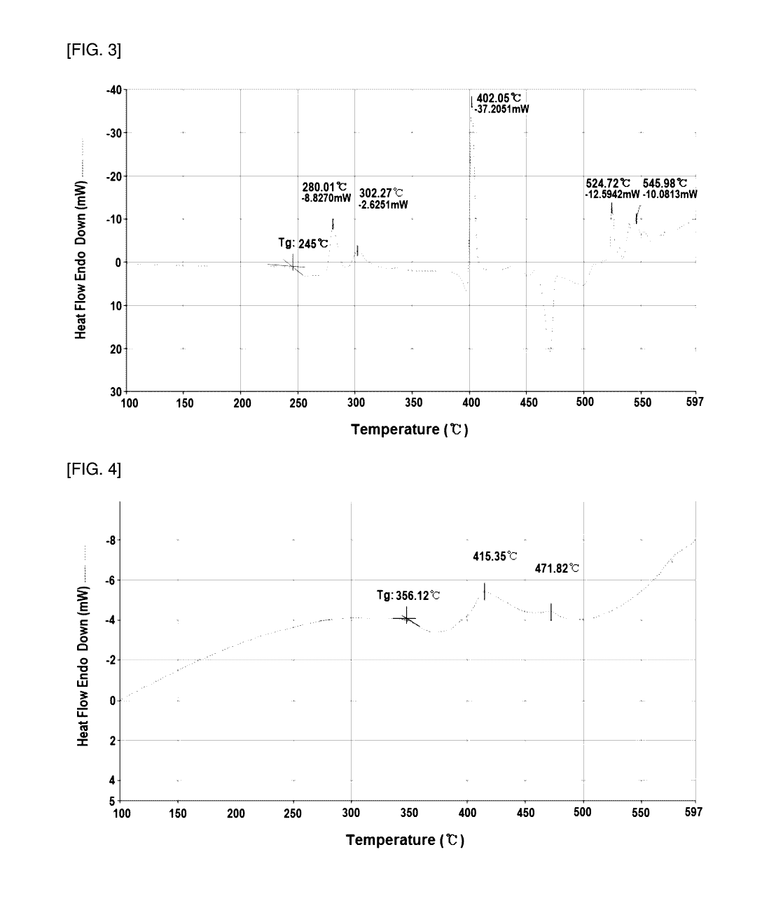

TLM patterns and a CoreScan tester were used to evaluate contact resistance. The results are given in FIGS. 3 and 4.

(2) Test of Production of Ag Precipitates on Surface of Electrode

Ag precipitates formed on the surface of the n layer were observed by scanning electron microscopy (SEM), after the electrode patterns formed on the cell surface were etched by immersing the electrode patterns in a 30% hydrofluoric acid solution for several s to 3 min.

(3) Electrical Characteristics

Electrical characteristics (I-V curve) of solar cell substrates were evaluated by using a solar simulator, and the results are given in Table 5.

TABLE 5

| | | Comparative |
|---|---|---|
| | Example 9 | Example 6 |
| Series resistance | 1.52 | 4.24 |
| (mΩ) | | |
| Short circuit current | 8.672 | 8.665 |
| (A) | | |
| Open circuit voltage | 0.625 | 0.624 |
| (V) | | |
| Fill factor (%) | 79.22 | 74.31 |
| Energy conversion | 17.64 | 16.51 |
| efficiency (%) | | |

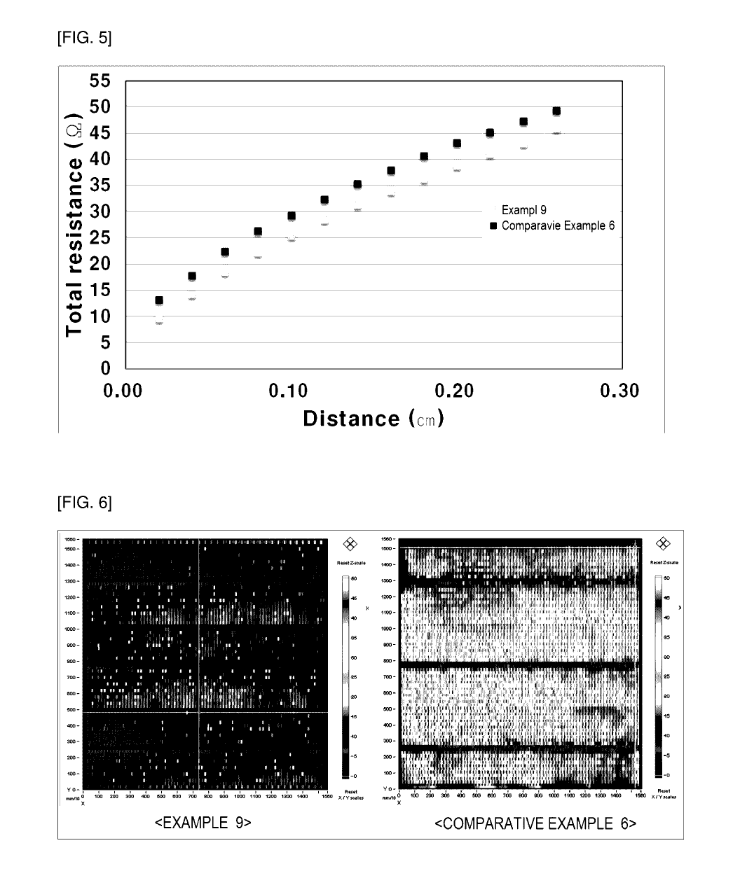

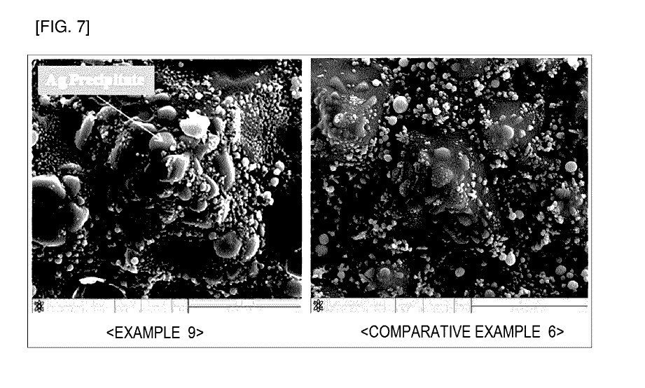

The results of FIGS. 5 and 6 showed that contact resistance was greatly improved in Examples of the present invention, compared to Comparative Examples. In FIG. 7, Ag precipitates were increased on the surface of the n layer of the electrode of Example 9, suggesting improvement of contact resistance, as in FIGS. 5 and 6. However, a small amount of Ag precipitates was produced on the surface of the electrode of Comparative Example 6, and thus contact resistance was high to deteriorate performances of the cell.

The results of Table 5 show that Example 9 has lower series resistance and a higher fill factor than Comparative Example 6, in spite of high resistance of the substrate as in a high sheet resistance (90Ω/□ or more) structure, thereby improving energy conversion efficiency.

1. A glass composition showing three or more exothermic peaks in a range of 200° C. to 600° C., as measured by differential scanning calorimetry.

2. The glass composition of claim 1, comprising PbO, TeO₂, and Li₂O.

3. The glass composition of claim 1, further comprising one or more metal oxides selected from the group consisting of Na₂O, K₂O, Bi₂O₃, and SiO₂.

4. The glass composition of claim 2, not comprising B₂O₃ and P₂O₅.

5. The glass composition of claim 3, comprising at least one metal oxide composition selected from the metal oxide composition groups consisting of:
PbO, TeO₂, Li₂O, and Bi₂O₃;
PbO, TeO₂, Li₂O, Na₂O, and K₂O;
PbO, TeO₂, Li₂O, Na₂O, K₂O, and SiO₂;
PbO, TeO₂, Li₂O, Na₂O, K₂O, and Bi₂O₃; and
PbO, TeO₂, Li₂O, Na₂O, K₂O, Bi₂O₃, and SiO₂.

6. The glass composition of claim 1, not comprising a metal component or a metal oxide other than one or more metal oxides selected from the group consisting of Na₂O, K₂O, Bi₂O₃, and SiO₂.

7. The glass composition of claim 1, which consists essentially of a metal oxide composition of any one selected from the metal oxide composition groups consisting of:
PbO, TeO₂, Li₂O, and Bi₂O₃;
PbO, TeO₂, Li₂O, Na₂O, and K₂O;
PbO, TeO₂, Li₂O, Na₂O, K₂O, and SiO₂;
PbO, TeO₂, Li₂O, Na₂O, K₂O, and Bi₂O₃; and
PbO, TeO₂, Li₂O, Na₂O, K₂O, Bi₂O₃, and SiO₂.

8. The glass composition of claim 2, comprising 20% by weight to 70% by weight of PbO, 20% by weight to 70% by weight of TeO₂, and 0.1% by weight to 20% by weight of Li₂O, based on the total weight of the glass composition.

9. The glass composition of claim 3, wherein a content of the metal oxide is 0.1 to 30 parts by weight, based on the total 100 parts by weight of PbO, TeO₂, and Li₂O.

10. The glass composition of claim 1, wherein a glass transition temperature (Tg) is 200 to 400° C.

11. The glass composition of claim 1, wherein a glass transition temperature (Tg) is 200 to 300° C.

12. An electrode composition comprising a conductive particle, a glass composition according to claim 1, a binder, and a solvent.

13. The electrode composition of claim 12, wherein a content of the glass composition is 0.1% by weight to 20% by weight, based on the total paste composition.

14. The electrode composition of claim 12,
wherein a content of the conductive particle is 45% by weight to 95% by weight, based on the total paste composition,
wherein a content of the binder is 0.1% by weight to 10% by weight, based on the total paste composition, and
wherein a content of the solvent is 1% by weight to 40% by weight, based on the total paste composition.

15. The electrode composition of claim 12, which further comprises the additive at 0.01 parts by weight to 10 parts by weight, based on 100 parts by weight of the electrode composition.

16. The electrode composition of claim 12, wherein the conductive particle comprises Ag, Cu, or Ni particles having an average diameter of 10 nm to 10 um.

17. The electrode composition of claim 12, wherein the binder is one or more selected from the group consisting of cellulose derivatives such as methyl cellulose, ethyl cellulose, nitrocellulose, hydroxy cellulose, or cellulose acetate; an acrylic resin; an alkyd resin; a polypropylene-based resin; a polyvinyl chloride-based resin; a polyurethane-based resin; an epoxy-based resin; a silicon-based resin; a rosin-based resin; a terpene-based resin; a phenolic resin; an aliphatic petroleum resin; an acrylic ester-based resin; a xylene-based resin; a cumaronindene-based resin; a styrene-based resin; a dicyclopentadiene-based resin; a polybutene-based resin; a polyether-based resin; a urea-based resin; a melamine-based resin; a vinyl acetate-based resin; and a polyisobutyl-based resin.

18. The electrode composition of claim 12, wherein the solvent is one or more selected from the group consisting of butyl carbitol acetate, butyl carbitol, propylene glycol monomethyl ether, dipropylene glycol monomethyl ether, propylene glycol monomethyl ether propionate, ethyl ether propionate, propylene glycol monomethyl ether acetate, terpineol, texanol, (dimethylamino)formaldehyde, methylethylketone, gamma-butyrolactone, and ethyl lactate.

19. The electrode composition of claim 12, which is used to form a front electrode on a substrate having sheet resistance of 80Ω/□ or more.
